(19) United States
(12) Patent Application Publication
(10) Pub. No.: US 2010/0025862 A1
(43) Pub. Date: Feb. 4, 2010

(54) Integrated Circuit Interconnect Method and Apparatus

(76) Inventors: Peter Alfred Gruber, Mohegan Lake, NY (US); Jae-Woong Nah, Closter, NJ (US)

Correspondence Address: RYAN, MASON & LEWIS, LLP, 90 FOREST AVENUE, LOCUST VALLEY, NY, 11560, US

(21) Appl. No.: 12/181,882

(22) Filed: Jul. 29, 2008

(51) Int. Cl. H01L 23/52; H01L 21/00

(52) U.S. Cl. 257/778; 438/108; 257/E23.141; 257/E21.001

(57) ABSTRACT

Techniques for interconnecting an IC chip and a receiving substrate are provided. A method includes the steps of: providing the IC chip, the IC chip including at least a first connection site formed thereon; providing the receiving substrate, the receiving substrate including at least a second connection site formed thereon; forming an alloy structure on at least a portion of an upper surface of the second connection site; orienting the IC chip relative to the receiving substrate so that the at least first connection site is aligned with the alloy deposit formed on the at least second connection site; and forming an electrical connection between the first and second connection sites, the electrical connection comprising a volume of electrically conductive fusible material, wherein a majority of the volume of electrically conductive fusible material is supplied from the alloy structure.

### FIELD OF THE INVENTION

The present invention relates generally to electrical and electronic devices, and more particularly relates to semiconductor packaging and interconnection.

### BACKGROUND OF THE INVENTION

Flip chip technology, first introduced in the 1960's by IBM as the controlled collapse chip connection (C4) process, offers a viable and proven alternative to standard assembly technologies for products requiring enhanced performance. Flip chip is not a specific package (like small-outline integrated circuit (SOIC)), or even a package type (like ball grid array (BGA)). Rather, flip chip generally describes the method of electrically connecting an integrated circuit (IC) die, also referred to as a chip, to a package carrier. The package carrier, either substrate or leadframe, then provides the connection from the die to the exterior of the package. In “standard” IC packaging, the interconnection between the die and the carrier is made using bond wires, which exhibit disadvantages, particularly in high-frequency applications (e.g., about one gigahertz and above).

Flip chip has become popular primarily because it offers good electrical performance, small package size, and the capability of handling a relatively large number of input/output (I/O) connections. Early flip chip processing employed solder bumps formed on chip I/O pads. These solder bumps align with corresponding pad sites on the substrate. The solder bumped die is attached to the substrate by a solder reflow process, very similar to the process used to attach BGA balls to the package exterior. After the die is attached, underfill is added between the die and the substrate to control the stress in the solder joints caused by the difference in thermal expansion between the silicon die and the carrier. Once cured, the underfill absorbs the stress, reducing the strain on the solder bumps, greatly increasing the life of the finished package. The die attach and underfill steps are the basics of flip chip interconnect.

Using conventional solder bumping technology, when solder bumps are formed on the substrate, the semiconductor wafer is exposed to wet processing and high temperature associated with reflow of the solder bumps. In some cases, the choice of under bump metallurgy (UBM), which generally refers to the pad metallurgy used to protect the IC while making a good mechanical and electrical connection to the solder bump and the substrate, may be limited by the solder bumping process. For example, sputtered UBM is generally used with electroplated solder bumping because electroplating solder requires an electrically connected seed layer for deposition. After electroplated solder bumping, the sputtered seed layer, except under the solder bumps, is etched away. Chip yield loss associated with solder bumping increases the overall cost of flip chip technology. Chip yield loss is at least partially attributable to process steps associated with conventional solder bumping, such as, for example, a vacuum process for sputtering UBM, a lithography process for patterning photoresist, and a wet etching process for patterning UBM. As another example, electroless plated UBM is often used with screen printed solder bumping, primarily because screen printed solder bumping uses a printing mask and can form solder bumps even though the UBM is not electrically connected.

Screen printing is another known methodology for applying solder bumps to input/output (I/O) pads on a substrate due, at least in part, to its relatively low cost. Screen printing can be used to directly form solder bumps on I/O pads without additional metal deposition which is needed for electroplating solder as a seed layer.

Known techniques are generally not useful for forming solder bumps on substrates, primarily because additional metal deposition and etching processes followed by electroplated solder bumping is very expensive as a solder bumping method on substrates. Screen printing, although less expensive, has limited use for making high volume solder bumps on substrates due primarily to volume reduction of the solder paste in the screen printing process. For this reason, solder bumps on the substrate have, thus far, been limited to low volume solder bumps used as a pre-solder. The majority of the solder volume of flip chip die to substrate (CS) connections comes from solder bumps formed on the chip die, which is undesirable.

### SUMMARY OF THE INVENTION

Illustrative embodiments of the present invention provide techniques for forming high volume solder features on a substrate and employing the high volume solder features in forming CS connections, wherein substantially all, or at least a majority, of the solder forming the connections comes from the high volume solder features formed on the substrate. The high volume solder features may be formed on the substrate using, for example, an injection molded soldering (IMS) process. Advantages of the invention include, for example, reduced cost of flip chip packaging, increasing reliability of flip chip packaged ICs due primarily to elimination of solder bumping on the chip, avoiding wet and high temperature processing related to solder bumping on the chip, and reducing the consumption of chip pad metal by eliminating a reflow process related to solder bumping.

In accordance with one aspect of the invention, a method for interconnecting an IC chip and a receiving substrate is provided. The method includes the steps of: providing the IC chip, the IC chip including at least a first connection site formed thereon; providing the receiving substrate, the receiving substrate including at least a second connection site formed thereon; forming an alloy structure on at least a portion of an upper surface of the second connection site; orienting the IC chip relative to the receiving substrate so that the at least first connection site is aligned with the alloy deposit formed on the at least second connection site; and forming an electrical connection between the first and second connection sites, the electrical connection comprising a volume of electrically conductive fusible material, wherein a majority of the volume of electrically conductive fusible material is supplied from the alloy structure.

In accordance with another aspect of the invention, an IC is provided. The IC comprises a chip including at least a first connection site formed thereon, a receiving substrate including at least a second connection site formed thereon, the first connection site being aligned with an alloy structure formed on at least a portion of the second connection site. The IC further includes a connection electrically coupling the first and second connection sites. The connection comprises a volume of fusible material, a majority of the volume of fusible material being supplied from the alloy structure.

These and other features, objects and advantages of the present invention will become apparent from the following detailed description of illustrative embodiments thereof, which is to be read in connection with the accompanying drawings.

### BRIEF DESCRIPTION OF THE DRAWINGS

FIGS. 1A through 1E are cross-sectional views depicting an illustrative process for forming an exemplary flip chip connection using high volume solder bumps formed on the chip.

FIGS. 2A through 2D are cross-sectional views depicting an exemplary process for forming high volume solder structures in cavities of decals, in accordance with an embodiment of the present invention.

FIGS. 3A and 3B are cross-sectional views depicting an exemplary process for transferring high volume solder structures from a decal to a substrate, in accordance with an embodiment of the present invention.

FIGS. 4A through 4F are cross-sectional views depicting an exemplary process for forming a CS connection, in accordance with an embodiment of the present invention.

FIG. 5 is a cross-sectional view depicting an exemplary packaged integrated circuit, comprising CS connections formed using high volume substrate solder structures, in accordance with an embodiment of the present invention.

### DETAILED DESCRIPTION OF THE INVENTION

The present invention will be described herein in the context of illustrative embodiments of a methodology for forming high volume solder features on a substrate and an IC device employing same. It is to be appreciated, however, that the techniques of the present invention are not limited to the specific methods and device shown and described herein. Rather, embodiments of the invention are directed broadly to improved techniques for interconnecting an IC die to a substrate using high volume alloy deposits. For this reason, numerous modifications can be made to these embodiments and the results will still be within the scope of the invention. No limitations with respect to the specific embodiments described herein are intended or should be inferred.

Although combined in a novel manner, several of the processing steps described herein may be performed in conventional semiconductor processing, and, as result, will be familiar to those skilled in that art. Moreover, details of certain individual processing steps used to fabricate semiconductor devices described herein may be found in a number of publications, for example, S. Wolf and R. N. Tauber, Silicon Processing for the VLSI Era, Volume 1, Lattice Press, 1986; S. Wolf, Silicon Processing for the VLSI Era, Vol. 4: Deep-Submicron Process Technology, Lattice Press, 2003; and S. M. Sze, VLSI Technology, Second Edition, McGraw-Hill, 1988, which are incorporated herein by reference. It is also emphasized that the descriptions provided herein are not intended to encompass all of the processing steps which may be required to successfully form a functional device. Rather, certain processing steps which are conventionally used in forming integrated circuit devices, such as, for example, wet cleaning and annealing steps, are purposefully not described herein for economy of description. However one skilled in the art will readily recognize those processing steps omitted from this generalized description.

It should also be understood that the various layers and/or regions shown in the accompanying figures may not be drawn to scale, and that one or more semiconductor layers and/or regions of a type commonly used in such ICs may not be explicitly shown in a given figure for ease of explanation. This does not imply that the semiconductor layers and/or regions not explicitly shown are omitted from the actual IC device.

The term chip, as used herein, is intended to refer broadly to an integrated circuit chip, integrated circuit die, or chip die, which is typically formed by dicing a wafer. The term chip, as used herein, does not generally include the integrated circuit leadframe or receiving substrate to which the chip is attached, and does not generally include the interconnect material between the chip and leadframe or substrate. The term substrate, as used herein, is intended to refer broadly to the substrate or leadframe for coupling to the chip die. The term solder-less chip, as used herein, is intended to refer broadly to a chip that does not have solder bumps attached to pads, or alternative bonding sites, on the chip prior to attachment to a substrate, or to a chip die that has only minimal solder attached to pads within the chip prior to bonding to the substrate; that is, the solder on the chip pads does not provide the majority of solder in the connection between the chip pads and the substrate. The connection between the chip and substrate typically does contain solder; however, the source of the solder is not solder previously formed on the chip bond pads. The term high volume solder bumps, or high volume solder features, or high volume alloy deposits, as used herein, is intended to refer broadly to solder bumps or features, or alternative alloy deposits, structures, or features, containing a majority of solder or other electrically conductive fusible material that will form a connection between the chip die and the substrate. The term CS connection, as used herein, is intended to refer broadly to a connection between a pad on the chip die and a pad on the corresponding substrate.

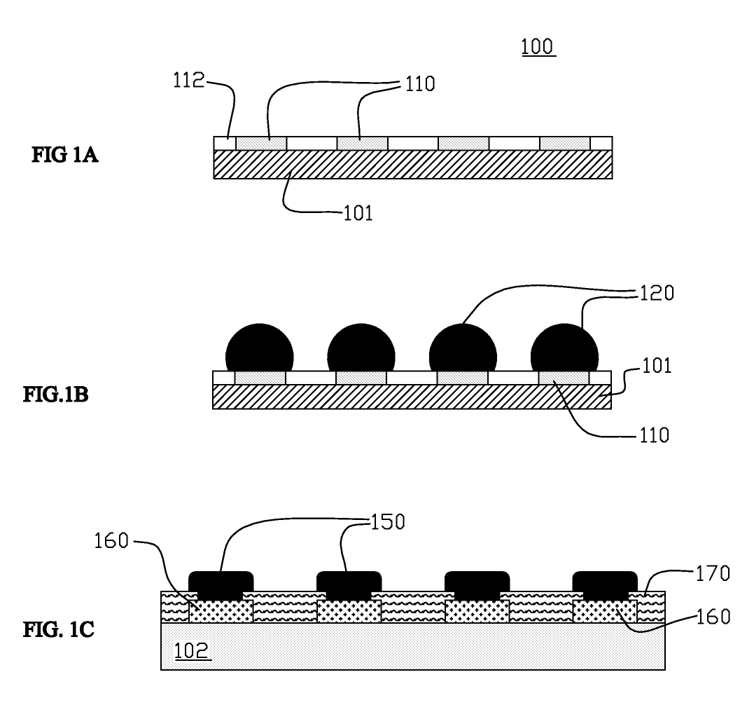

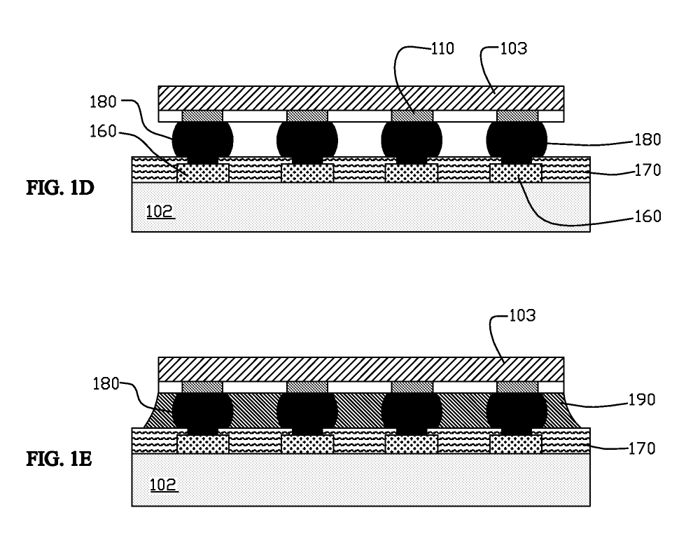

FIGS. 1A through 1E are cross-sectional views depicting an illustrative process 100 for forming an exemplary flip chip connection using high-volume solder bumps formed on the chip. With reference to FIG. 1A, a wafer 101, or alternative substrate, is shown, including a plurality of ball-limiting metallurgy (BLM) sites 110, or alternative connection sites, formed on at least a portion of an upper surface of the wafer. Adjacent BLM sites 110 are preferably separated from one another by a layer of insulating material 112, such as, for example, silicon dioxide. Wafer 101 is preferably formed of a semiconductor material, such as, but not limited to, silicon, germanium, gallium arsenide, etc., which may be doped to a desired conductivity, as will be known by those skilled in the art. As depicted in FIG. 1B, high volume solder bumps 120 are formed on an upper surface of the respective BLM sites 110 using, for example, electroplating, stencil mask printing, ball mounting, and/or C4NP (C4 new process) methods.

With reference now to FIG. 1C, a receiving substrate 102 is shown including a plurality of pads 160, or alternative connection sites, formed on at least a portion of an upper surface of the substrate. Substrate 102 may comprise, for example, an organic material, including, but not limited to flame retardant type 4 (FR-4), bismaleimide triazine (BT) resin, etc., or a semiconductor material, such as, for example, silicon, germanium, gallium arsenide, etc. Optionally, a solder mask 170, or alternative spacer, may be employed (as shown) to prevent bridging of solder between adjacent pads 160. Pre-solder bumps 150 may be formed on an upper surface of pads 160 to help facilitate formation of the flip chip connection.

In FIG. 1D, a chip 103, which is diced from wafer 101 and includes the plurality of high volume solder bumps 120 formed thereon (FIG. 1B), is flipped upside-down and placed on the substrate 102 such that the plurality of solder bumps 120 (FIG. 1B) are substantially aligned with corresponding pads 160 on the substrate. The substrate 102 and surrounding environment are then elevated to a high temperature, typically about 30 to 40 degrees Celsius (° C.) above the melting temperature of the components in the solder bumps (e.g., greater than about 210° C. for eutectic tin-lead (SnPb) solder (melting point 183° C.) and greater than about 250° C. for lead-free solder (melting point around 220° C.)). This solder reflow step can be carried out using, for example, forced air convection, infrared furnace, vapor phase, etc. By exposing the substrate to the elevated temperature, the solder bumps will melt to form molten solder balls against the upper surface of the solder mask 170. The result is the formation of a plurality of CS connections 180 between respective BLM sites 110 on chip 103 and corresponding pads 160 on substrate 102.

FIG. 1E illustrates an underfill process, whereby one or more spaces between the chip 103 and substrate 102 (e.g., between adjacent CS connections 180) is substantially filled with an underfill material 190. Underfill material 190 is typically electrically non-conductive to thereby prevent adjacent CS connections 180 from being electrically shorted to one another.

The majority of the solder volume of the CS connections 180 comes from solder bumps 120 formed on the chip die 101 (see FIG. 1B), which is undesirable. While it is advantageous to form high volume solder bumps on the receiving substrate 102, known techniques are generally not useful for forming high volume solder bumps on substrates, primarily because required additional metal deposition and etching processes, followed by electroplated solder bumping, are cost prohibitive. Screen printing, although less expensive, has limited use for making high volume solder bumps on substrates due primarily to volume reduction of the solder paste used in the screen printing process. For this reason, solder bumps formed on the substrate have, thus far, been limited to low volume solder bumps used as a pre-solder.

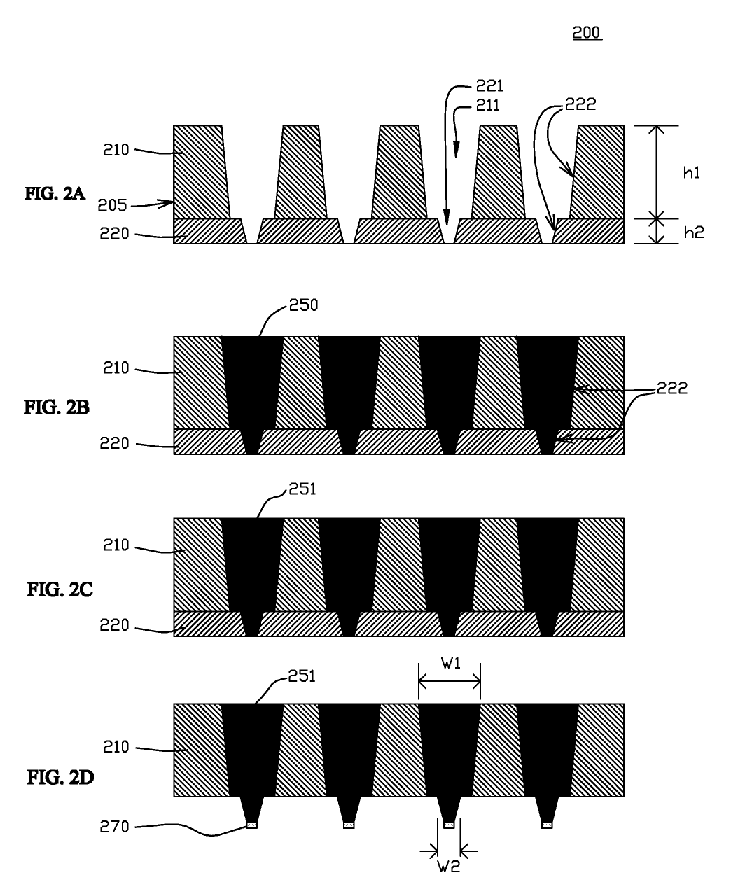

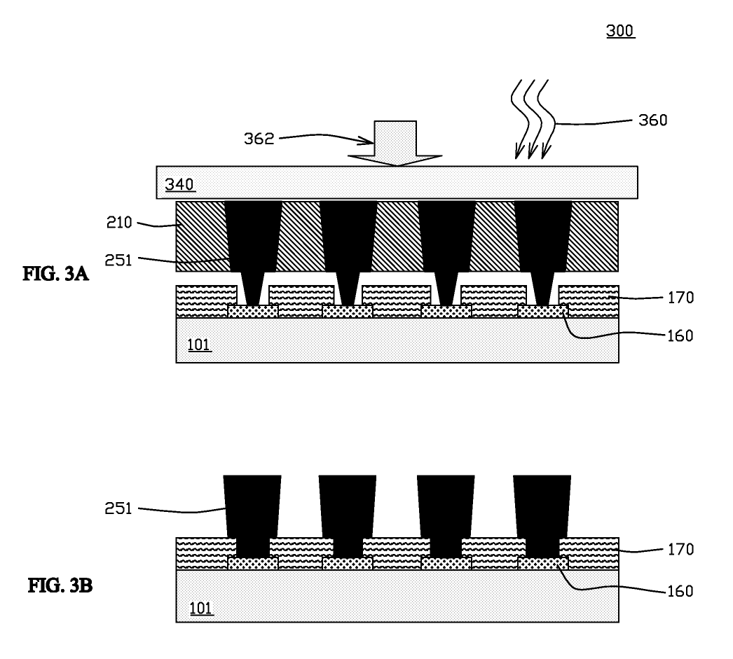

FIGS. 2A through 2D are cross-sectional views depicting at least a portion of an exemplary process 200 for forming high volume solder bumps on a substrate, in accordance with an embodiment of the present invention. Illustrative process 200 provides a method of forming CS connections wherein all or a majority of alloy material forming the connections is supplied from high volume solder structures, or alternative alloy deposits, formed on the substrate. The high volume solder structures can be formed on the substrate using, for example, a simplified injection molded soldering (IMS) process. Upper surfaces of the respective solder structures are made substantially coplanar relative to one another. Moreover, the illustrative IMS process advantageously eliminates the need for two-step processes of solder reflow step followed by a solder coining step, as required by the stencil printing process depicted in FIGS. 1A through 1H.

Referring now to FIG. 2A, a first step in an embodiment of the invention is illustrated. In this step, a decal solder alloy carrier 205 is formed including at least a first decal 210 and a second decal 220. As is known by those skilled in the art, the term “decal” generally refers to a structure (e.g., a mold) for forming and holding solder, which is initially in molten form when injected into the decal. First and second decals are preferably held together using mechanical means (e.g., clamps, elastic, etc.). Although only two decals are depicted in the figure, it is to be understood that the present invention is not limited to any particular number of decals used to form the solder alloy carrier 205. The relatively large composite thickness of the first decal 210, h1, and/or second decal 220, h2, used in the IMS process enables high volume alloy deposits to be formed on the substrate. Because at least one of the decals is relatively thick, the decal can advantageously hold enough solder to supply all, or at least a majority, of the solder forming the CS connection.

The thickness h1 of first decal 210 is preferably greater than the thickness h2 of second decal 220 (e.g., h1≧2×h2). For example, the thickness h1 of first decal 210 may be in a range from about 30 microns (μm) to about 100 μm, and the thickness h2 of second decal 220 may be about 30 μm or less. It is to be understood, however, that the invention is not limited to any particular dimensions for the first and second decals 210, 220. Preferably, first decal 210 has a thickness h1 that is at least equal to a minimum diameter of an opening 211 within the first decal. A height of the opening 211 in the first decal 210 is substantially the same as the thickness h1 of the first decal 210. Likewise, a height of an opening 221 in second decal 220 is substantially the same as the thickness h2 of second decal 220. By virtue of the thickness of at least first decal 210, the first decal, along with second decal 220, is adapted to contain a large volume of solder.

Decal solder alloy carrier 205 is preferably formed of a material that is non-wettable by solder alloys typically used in the semiconductor technology field, i.e., a material that has no metallurgical affinity with, and thus does not metallurgically bond to the solder alloy. In one illustrative embodiment of the invention, decal solder alloy carrier 205 is formed of a material having a relatively low thermal expansion coefficient, particularly a thermal expansion coefficient sufficiently lower than that of a target substrate onto which the solder alloy is to be transferred. In an illustrative embodiment, the decals 210, 220 are comprised of, for example, a polyimide material such as Kapton® (a registered trademark of E.I. du Pont de Nemours and Company). First decal 210 need not be formed of the same material as that of second decal 220, although the first and second decals may be formed of the same material. Suitable materials for forming the decal solder alloy carrier 205 include, but are not limited to, polymer, silicon, germanium, gallium arsenide, glass, quartz, and like materials and/or compositions.

First decal 210 includes a first plurality of openings 211 therein adapted for carrying solder alloy. Likewise, second decal 220 includes a second plurality of openings 221 therein adapted for carrying solder alloy. The openings 211 and 221 may be formed, for example, using a conventional laser drilling process and/or a photolithographic process, although alternative means for forming the openings are similarly contemplated (e.g., wet or dry etch, bulk micromachining, surface micromachining). The first and second decals 210, 220 are preferably arranged in abutting contact with one another such that each of the first plurality of openings 211 is in alignment with a corresponding one of the second plurality of openings 221, as shown. Each opening 211 in the first decal 210 and corresponding opening 221 in the second decal 220 forms a composite opening 222 in the decal solder alloy carrier 205. Openings 211 and 221 do not have to be the same diameter or shape. In alternative embodiments in which more than two decals are employed, there will be openings in each decal that are aligned such that there are composite openings that are continuous through all the decals.

FIG. 2B depicts the first and second decals 210, 220 after substantially filling composite openings 222 with molten solder 250, or an alternative molten material. The molten solder 250 may be injected into composite openings according to an IMS process, for example, as described in U.S. Pat. No. 5,673,846, which is incorporated by reference herein, although other means may be similarly employed for filling the composite openings. In general terms, IMS provides for injecting molten solder into the openings 222 formed in the decals 210, 220, and then cooling the solder down, or allowing the solder to cool, so that the solder solidifies within the openings, resulting in the formation of high volume solid solder plugs 251, or alternative alloy structures, as shown in FIG. 2C. Typically, however, solder plugs 251 will not have as flat or as level an upper surface as desired. Planarization of the solder plugs 251 is performed in a subsequent processing step, as will be described in further detail below.

With reference to FIG. 2D, subsequent to cooling, second decal 220 is removed. Removal of the second decal 220 exposes at least a portion of solder plugs 251, such as a lower portion, thereby allowing the solder plugs to extend through material intervening between first decal 210 and the target substrate for electrical connection to corresponding pads on the substrate. For example, the intervening material may be solder mask 170 formed on substrate 101, as shown in FIG. 1A. The solder plugs 251 preferably remain in first decal 210 without falling through since a first width, W1, of a given opening at an upper surface of the first decal is preferably larger than a second width, W2, of the opening at a bottom surface of the first decal. The reach with which the exposed portions of the respective solder plugs 251 may extend through the intervening material for connection to the substrate will, inherently, be a function of the cross-sectional thickness of the second decal 220 (e.g., about 20 μm). Optionally, a layer of flux 270 may be formed on a bottom surface of each of the solder plugs 251 for improving solder wetting on the pads when the solder plugs are placed in contact with corresponding pads on the substrate so as to facilitate adhesion of the solder plugs to the corresponding pads on the substrate. Alternatively, a formic acid vapor may be applied during the solder transfer process, wherein the formic acid vapor is operative to remove oxide layers and improve adhesion of the exposed solder to the pads. Following the formation of the high volume solder plugs 251 in first decal 210, the solder plugs are bonded to corresponding pads on a receiving substrate.

FIGS. 3A and 3B are cross-sectional views depicting an exemplary process 300 for bonding high volume solder structures to a substrate, in accordance with an embodiment of the present invention. Referring now to FIG. 3A, solder plugs 251 in first decal 210 are substantially aligned to corresponding pads 160 formed on an upper surface of a substrate 101. As previously described in conjunction with FIG. 1A, a solder mask 170, or an alternative spacer, may be optionally formed on the upper surface of the substrate 101 to prevent bridging of solder between adjacent pads 160. Bridging between solder features is a concern and should be avoided. Because first decal 210 holds the solder during the process of transferring the solder plugs 251 to the substrate 101, bridging can be essentially eliminated while forming columnar-shaped, high volume solder features.

Solder mask 170, when used, includes a plurality of openings therein, each of the openings being aligned with a corresponding one of the pads 160. Under prescribed heat 360 and/or compressive force 362 applied to a bar 340, or alternative structure suitable for uniformly transferring the compressive force and/or heat to solder plugs 251, the solder plugs are bonded to the corresponding pads 160. That is, solder plugs 251 are under sufficient pressure and/or heat for a sufficient time as required to bond to pads 160.

In this embodiment, the heat is preferably not sufficient to reflow the solder plugs 251; that is, the solder comprised in the solder plugs is not fully melted to form molten solder. In accordance with an alternative embodiment, sufficient heat is applied to reflow the solder plugs 251. In still another alternative embodiment, mechanical vibration may be applied to solder plugs 251 to assist in bonding to corresponding pads 160. In this instance, vibrational wetting support can be used to supplement standard oxide removal methods. In yet another alternative embodiment, bonding of the solder plugs 251 to corresponding pads 160 is performed under a compressive force 362, without the addition of heat to the bar 340. However, this step preferably takes place in a heated environment, wherein the temperature of the environment may be slightly above the melting point of the solder material forming the solder plugs 251 (e.g., greater than about 180° C. for eutectic SnPb solder and about 220° C. for lead-free solder). Although the solder material forming the solder plugs 251 does melt during transfer, the solder material is constrained by the surrounding geometry/structure, including the top compressive force. These constraining structures and/or force are applied until the solder material has solidified, and thus the solder plugs retain this columnar shape. Although FIG. 3A shows heat 360 and compressive force 362 applied to the bar 340, the invention is not so limited. Heat 360 and compressive force 362 can, alternatively or in addition, be applied to the substrate 101. Moreover, the compressive force 362, although shown as being applied to an upper surface of the solder plugs 251, can, alternatively or in addition, be applied to a backside of the substrate 101. Mechanical vibration can be applied to the bar 340, the substrate 101, both the substrate and bar, or neither.

Another function of bar 340 is to form substantially flat and level upper surfaces of solder plugs 251, such that the upper surfaces of the solder plugs reside in substantially the same plane, i.e., coplanar. Application of compressive force 362 to the bar 340 and/or the substrate 101 causes pressure between the bar 340 and solder plugs 251. The pressure between bar 340 and solder plugs 251 causes the upper surfaces of the respective solder plugs 251 to flatten and thereby become substantially coplanar with one another. Likewise, heat 360, when applied, assists in reshaping (reforming) the upper surfaces of solder plugs 251 so as to be substantially flat and coplanar relative to one another. That is, the solder plugs 251 are preferably placed under sufficient pressure and/or heat for a sufficient time so as to produce substantially flat-topped, coplanar solder plugs. During this step, first decal 210 functions to prevent bridging of solder between adjacent plugs.

As shown in FIG. 3B, bar 340 and first decal 210 are preferably removed. Remaining are high volume solder plugs 251 bonded on corresponding pads 160 formed on the upper surface of substrate 101, and, optionally, solder mask 170 formed on the upper surface of the substrate. As depicted in the figure, compressive force 261 and/or heat 262 applied to the bar 240 (FIG. 2F) preferably causes the solder alloy material forming the lower portion of solder plugs 251 to substantially fill openings in the solder mask 170 aligned with corresponding pads 160. Accordingly, the lower portions of solder plugs 251 will take on the shape of the openings in solder mask 170. In this manner, the high volume solder plugs 251 are transferred to the receiving substrate, for example, by applying a compressive force 362, applying heat 360, and/or by applying mechanical vibration to the solder plugs and/or the substrate.

The solder plugs 251 formed in accordance with the teachings herein are preferably columnar in shape, although not limited to being columnar, and are tall enough to form connections to chip pads, wherein, prior to forming the connections, the chip pads do not have solder bumps attached. The height of the columnar solder plugs can be controlled by adjusting the compressive force 362 (FIG. 3A) as desired. The high volume solder plugs 251 formed on substrate 101 contain a sufficient volume of solder as to form CS connections. The solder plugs formed in this manner hold at least approximately the same volume of solder as other types of CS connections comprising only solder from the chip pads, or mostly solder from the chip pads and lesser solder from the substrate pads, and do not exhibit the problems typically associated with conventional CS connection methodologies.

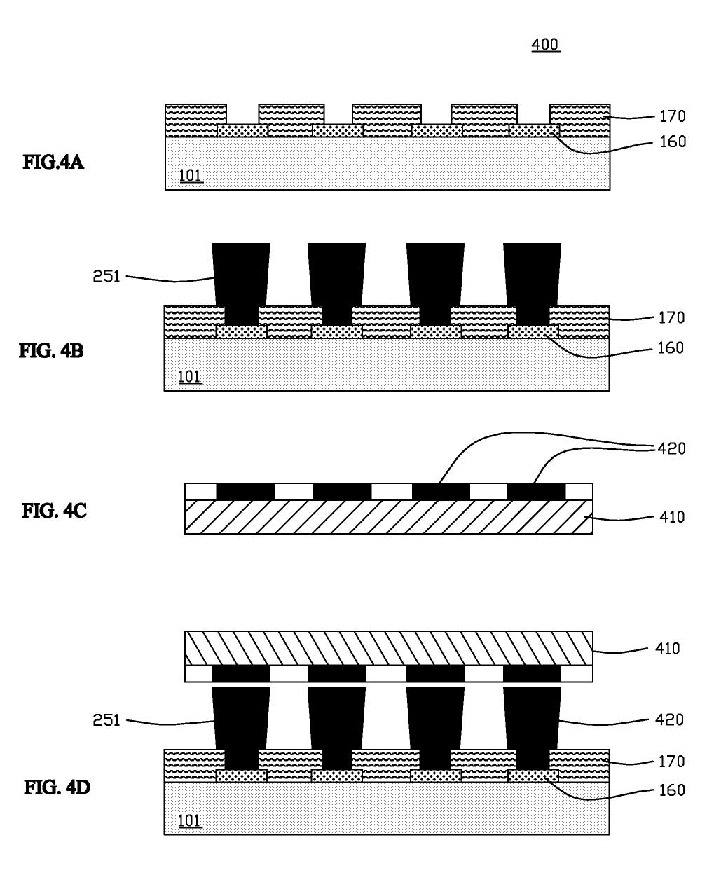

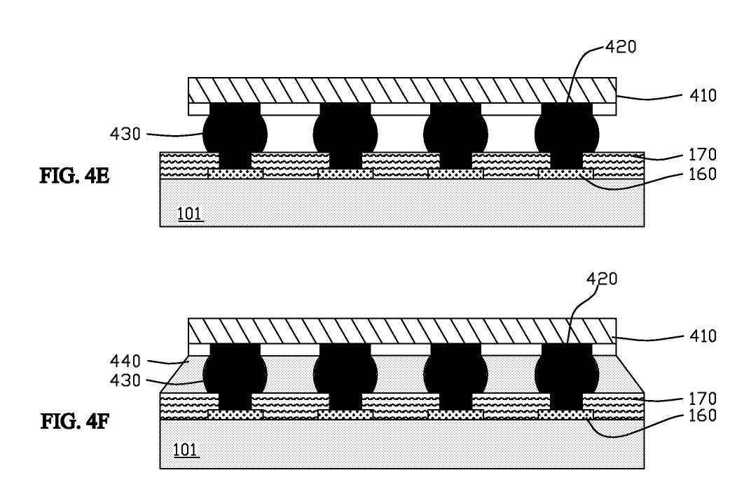

FIGS. 4A through 4F are cross-sectional views depicting an exemplary process for forming a CS connection, in accordance with an embodiment of the present invention. FIG. 4A illustrates at least a portion of a substrate 101 including a plurality of pads 160, or alternative connection sites, formed thereon and, optionally, a solder mask 170 formed on at least a portion of an upper surface of the substrate. The solder mask 170 includes a plurality of openings therein, each opening being aligned with a corresponding one of the pads 160. Substrate 101 may comprise, for example, an organic material, including, but not limited to flame retardant type 4 (FR-4), bismaleimide triazine (BT) resin, etc., or a semiconductor material, such as, for example, silicon, germanium, gallium arsenide, etc. FIG. 4B shows a plurality of high volume solder plugs 251, or alternative alloy structures, each solder plug being bonded to a corresponding one of the pads 160 formed on the substrate 101. Solder plugs 251 may be formed in a manner consistent with the exemplary method 200 depicted in FIGS. 2A through 2D and described herein above, although it is to be understood that the invention is not limited to forming the solder plugs in this manner.

With reference now to FIG. 4C, at least a portion of an illustrative solderless chip 410 is shown, including a plurality of chip pads 420, or alternative connection sites, formed on an upper surface of the chip. Each of the pads 420 on chip 410 are to be connected to a corresponding one of the pads 160 on substrate 101. In accordance with one aspect of the invention, alloy material (e.g., solder) for forming an electrical connection between the chip 410 and substrate 101 is not supplied from the pads 420 on the chip. In an alternative embodiment, pads 420 may supply a relatively small amount of solder, or alternative alloy, for forming the CS connection, while a majority of the solder is supplied by the high volume solder plugs 251 formed on the substrate. The amount of solder on a given chip pad 420 is substantially less than the volume of solder supplied by a corresponding high volume solder plug 251. As previously stated, the majority of the solder volume in conventional CS connections is supplied from solder bumps formed on the chip die, which is undesirable.

In FIG. 4D, the chip 410 is oriented such that the pads 420 formed thereon are facing and aligned with the corresponding solder plugs 251 formed on substrate 101. Chip 410 is then placed on the solder plugs 251 such that each of the pads 420 are brought into direct physical, and electrical, contact with a corresponding one of the pads 160 formed on the substrate 101.

As shown in FIG. 4E, solder reflow is preferably subsequently performed. During reflow, a temperature of the solder plugs 251 is preferably elevated, such as by elevating the temperature of the chip 410, the substrate 101, or both (e.g., the chip environment), typically about 30 to 40 degrees Celsius (° C.) above the melting temperature of the components in the solder paste (e.g., greater than about 210° C. for eutectic tin-lead (SnPb) solder (melting point 183° C.) and greater than about 250° C. for lead-free solder (melting point around 220° C.)) so that the solder plugs 251 become at least partially molten, thereby causing the solder plugs to form a wettable bond to the respective chip pads 420. This solder reflow step can be carried out using, for example, forced air convection, infrared furnace, vapor phase, etc. Typically, solder plugs 251 melt and re-solidify during reflow. The re-solidified solder is still in contact with pads 160 on the substrate 101. The result is formation of a plurality of CS connections 430, each connection being formed between a given pad 420 on chip 410 and a corresponding pad 160 on substrate 101.

FIG. 4E illustrates an optional underfill process, whereby one or more spaces between the chip 410 and substrate 101 (e.g., between adjacent CS connections 430) is substantially filled with an underfill material 440. Underfill material 440 is typically electrically non-conductive to thereby prevent adjacent CS connections 430 from being electrically shorted to one another. Underfill material 440 helps to absorb stresses resulting from, among other factors, a thermal expansion mismatch which may exist between the chip 410 and substrate 101, and the material(s) forming the CS connection 430 therebetween. Underfill 440 also protects the chip from, but not limited to, moisture, ionic contaminants, radiation, and hostile operating environments such as, for example, thermal and mechanical conditions, shock, and vibration. Underfill material 440 may comprise, for example, anhydride-cured or amine-cured epoxy materials, epoxy polymer, silsesquioxane-based epoxy resins, etc. In an illustrative embodiment, underfill material 400 comprises a liquid encapsulate, such as an epoxy resin heavily filled with SiO₂. The underfill material 440 preferably exhibits a high degree of capillary flow so as to allow penetration of the underfill material between the chip and the substrate after formation of the CS interconnections.

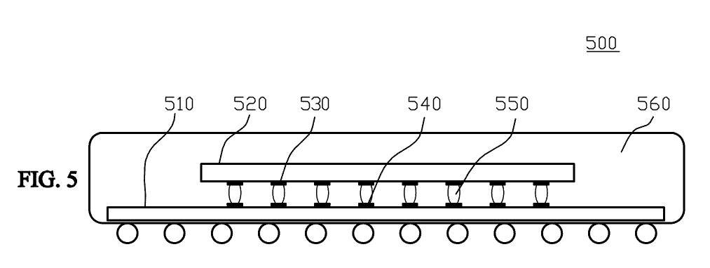

FIG. 5 is a partial cross-sectional view depicting an exemplary packaged IC 500 according to an embodiment of the present invention. The packaged IC 500 comprises a leadframe 510, or an alternative receiving substrate, a plurality of pads 540 formed on an upper surface of the leadframe, an IC die 520, and a molded encapsulation 560. The die 520 is attached to the leadframe 510 by methods of this invention described herein. For example, bonding pads 530 formed on an outer surface (e.g., bottom) of die 520 may be electrically connected to corresponding pads 540 formed on the upper surface of leadframe 510 via respective solder plugs 550. Encapsulation 560 preferably surrounds the die/leadframe combination, as in a conventional manner. Although FIG. 5 shows only one type of integrated circuit package, the invention is not so limited. Rather, the invention may comprise an integrated circuit die enclosed in essentially any package type.

At least a portion of the techniques of the present invention may be implemented in one or more integrated circuits. In forming integrated circuits, die are typically fabricated in a repeated pattern on a surface of a semiconductor wafer. Individual die are cut or diced from the wafer, then packaged as integrated circuits. In packaging the dies, individual die are attached to a receiving substrate according to methods of the invention. One skilled in the art would know how to dice wafers to produce integrated circuits. Integrated circuits so manufactured are considered part of this invention.

An integrated circuit formed in accordance with interconnection techniques of the present invention can be employed in essentially any application and/or electronic system. Suitable systems for implementing the invention may include, but are not limited to, personal computers, communication networks, portable communications devices (e.g., cell phones), etc. Systems incorporating such integrated circuits are considered part of this invention. Given the teachings of the invention provided herein, one of ordinary skill in the art will be able to contemplate other implementations and applications of the techniques of the invention.

Although illustrative embodiments of the invention have been described herein with reference to the accompanying drawings, it is to be understood that the invention is not limited to those precise embodiments, and that various other changes and modifications may be made therein by one skilled in the art without departing from the scope of the appended claims.

1. A method for interconnecting an integrated circuit chip and a receiving substrate, the method comprising the steps of:
providing the integrated circuit chip including at least a first connection site formed thereon;
providing the receiving substrate including at least a second connection site formed thereon;
forming at least one alloy structure on at least a portion of an upper surface of the at least second connection site;
orienting the integrated circuit chip relative to the receiving substrate so that the at least first connection site is aligned with the alloy structure formed on the at least second connection site;
forming at least one electrical connection between the at least first and at least second connection sites, the electrical connection comprising a volume of electrically conductive fusible material, wherein a majority of the volume of electrically conductive fusible material is supplied from the alloy structure;
wherein the step of forming the at least one alloy structure comprises forming a plurality of alloy structures on at least a portion of an upper surface of respective connection sites on the receiving substrate, the method further comprising the step of inserting a spacer between an alloy carrier and the receiving substrate, wherein the spacer is formed to avoid bridging of adjacent alloy structures formed on the receiving substrate.

2. The method of claim 1, wherein the step of orienting the integrated circuit relative to the receiving substrate comprises contacting the at least first connection site to the alloy structure.

3. The method of claim 1 further comprising the step of filling a space between the chip and the substrate with an underfill material.

4. The method of claim 3, wherein the underfill material comprises at least one of anhydride-cured epoxy, amine-cured epoxy, epoxy polymer, and silsesquioxane-based epoxy resin.

5. The method of claim 1, wherein the at least one alloy structure is formed having an upper portion adapted for attachment to the at least first connection site and a lower portion attached to the at least second connection site, a cross-sectional thickness of the upper portion of the at least one alloy structure being greater than a cross-sectional thickness of the lower portion of the at least one alloy structure.

6. The method of claim 1, wherein the step of forming the at least one alloy structure comprises:
providing the alloy carrier comprising at least a first decal including at least a first opening formed therein and a second decal including at least a second opening formed therein, the first and second decals being arranged in abutting contact with one another such that the at least first opening is in alignment with the at least second opening;
filling the first and second openings with molten alloy;
cooling the molten alloy in the first and second openings to thereby form the alloy structure;
removing at least one of the first and second decals to at least partially expose the alloy structure;
aligning the alloy carrier with the second connection site on the receiving substrate; and
transferring the alloy structure to the receiving substrate by bonding the at least partially exposed portion of the alloy structure to the second connection site on the receiving substrate.

7. The method of claim 6, wherein a cross-sectional thickness of the first decal forming an upper portion of the at least one alloy structure is greater than a cross-sectional thickness of the second decal forming a lower portion of the alloy structure.

8. The method of claim 6, wherein the step of inserting a spacer between an alloy carrier and the receiving substrate comprises inserting a spacer between one of the at least first and second decals and the receiving substrate.

9. The method of claim 6, wherein the step of transferring the alloy structure to the receiving substrate comprises at least one of applying a compressive force, applying heat, and applying mechanical vibration to at least one of the alloy structure and the substrate.

10. The method of claim 1, wherein the step of forming an electrical connection between the first and second connection sites comprises elevating a temperature of the at least one alloy structure so that reflow occurs, thereby causing the at least one alloy structure to form a wettable bond to the at least first connection site.

11. The method of claim 1, wherein the volume of electrically conductive fusible material is supplied substantially entirely from the at least one alloy structure.

12. The method of claim 1, wherein the electrically conductive fusible material is solder.

13-16. (canceled)

17. The method of claim 1, wherein the substrate comprises an organic material.
